(19) United States
(12) Patent Application Publication
(10) Pub. No.: US 2022/0236051 A1
(43) Pub. Date: Jul. 28, 2022

(54) METHOD FOR DETECTING ETCHING DEFECTS OF ETCHING EQUIPMENT

(71) Applicant: CHANGXIN MEMORY TECHNOLOGIES, INC., Hefei City (CN)

(72) Inventor: Yule SUN, Hefei City (CN)

(21) Appl. No.: 17/647,634

(22) Filed: Jan. 11, 2022

Related U.S. Application Data
(63) Continuation of application No. PCT/CN2021/113357, filed on Aug. 18, 2021.

(30) Foreign Application Priority Data
Jan. 25, 2021 (CN) 202110094612.1

(51) Int. Cl. G01B 11/24; H01L 21/66

(52) U.S. Cl. CPC G01B 11/24; H01L 22/12

(57) ABSTRACT

The present disclosure provides a method for detecting etching defects of an etching equipment, belonging to the field of semiconductor manufacturing technology. The method includes: providing a test wafer, the test wafer including a substrate, a first dielectric layer and a second dielectric layer, the first dielectric layer and the second dielectric layer being sequentially formed on a top surface of the substrate, and capacitor contact structures being disposed in the substrate; transferring the test wafer to the etching equipment to be detected, and etching part of the second dielectric layer and part of the first dielectric layer to form capacitor holes; removing the second dielectric layer to form a measured wafer; transferring the measured wafer to a defect detection equipment and detecting the shapes of the capacitor holes of the measured wafer.

### CROSS-REFERENCE TO RELATED APPLICATIONS

This is a continuation of International Application No. PCT/CN2021/113357, filed on Aug. 18, 2021, which claims the priority to Chinese Patent Application 202110094612.1, titled “METHOD FOR DETECTING ETCHING DEFECTS OF ETCHING EQUIPMENT”, filed on Jan. 25, 2021. The entire contents of International Application No. PCT/CN2021/113357 and Chinese Patent Application 202110094612.1 are incorporated herein by reference.

### TECHNICAL FIELD

The present disclosure relates to the field of semiconductor manufacturing technology, and in particular, to a method for detecting etching defects of an etching equipment.

### BACKGROUND

A dynamic random access memory is a semiconductor memory device commonly used in computers, and usually includes an array composed of a plurality of repeated memory cells. Each memory cell includes a capacitor and a transistor, wherein the capacitor is used to store data, and the transistor can control the access of the capacitor to data. Specifically, a gate of the transistor is electrically connected to a word line of the dynamic random access memory, one source/drain region of the transistor is electrically connected to a bit line of the dynamic random access memory, and the other source/drain region is connected to the capacitor by a capacitor contact structure, thereby achieving the purpose of data storage and output.

With the development of integrated circuit manufacturing processes, the geometric size of the memory cell of the dynamic random access memory continuously decreases, and the lateral area of the corresponding capacitor on the substrate gradually decreases. In order to obtain a relatively large capacitance, a stacked layer is usually formed on the substrate, and capacitor holes that exposes the capacitor contact structures are formed in the stacked layer by using an etching equipment, so that the subsequently formed capacitor structures have a relatively large contact area, and then capacitor structures with high capacitance are obtained. However, as the depth-to-width ratio of the capacitor holes continue to increase, the etching equipment fails to etch through the stacked layer during etching, so that the bottoms of the corresponding capacitor holes fail to expose the capacitor contact structures, which reduces device yield. However, the method for detecting the etching equipment in the prior art cannot detect this etching defect.

It should be noted that the information disclosed in the background section above is only used to enhance the understanding of the background of the present disclosure, and therefore may include information that does not constitute the prior art known to those of ordinary skill in the art.

### SUMMARY

According to the first aspect of the present disclosure, a method for detecting etching defects of an etching equipment is provided, including:

providing a test wafer, the test wafer including a substrate, a first dielectric layer and a second dielectric layer, the first dielectric layer and the second dielectric layer being sequentially formed on a top surface of the substrate, and capacitor contact structures being disposed in the substrate;

transferring the test wafer to the etching equipment to be detected, and etching part of the second dielectric layer and part of the first dielectric layer to form capacitor holes;

removing the second dielectric layer to form a measured wafer;

transferring the measured wafer to a defect detection equipment and detecting shapes of the capacitor holes of the measured wafer; and

detecting, according to the shapes of the capacitor holes of the measured wafer, whether the etching equipment to be detected has an etching defect.

It should be understood that the above general description and the following detailed description are only exemplary and explanatory, and cannot limit the present disclosure.

### BRIEF DESCRIPTION OF THE DRAWINGS

The accompanying drawings herein are incorporated into the specification and constitute a part of the specification, show embodiments consistent with the present disclosure, and are used to explain the principle of the present disclosure together with the specification. Apparently, the drawings described below are only some of the drawings of the present disclosure, and other drawings may also be obtained by those of ordinary skill in the art according to these drawings without any creative efforts.

FIG. 1 is a schematic flowchart of a method for detecting etching defects of an etching equipment in an exemplary embodiment of the present disclosure;

FIG. 2 is a schematic flowchart of a method for detecting etching defects of an etching equipment in another exemplary embodiment of the present disclosure;

FIG. 3 is a schematic flowchart of a method for detecting etching defects of an etching equipment in still another exemplary embodiment of the present disclosure;

FIG. 4 is a schematic flowchart of a method for detecting etching defects of an etching equipment in still another exemplary embodiment of the present disclosure;

FIG. 5 is a schematic step flowchart of a method for detecting etching defects of an etching equipment in an exemplary embodiment of the present disclosure;

FIG. 6 is a schematic structure diagram of a test wafer in an exemplary embodiment of the present disclosure;

FIG. 7 is a schematic structure diagram of forming a mask layer and a photoresist layer in an exemplary embodiment of the present disclosure;

FIG. 8 is a schematic structure diagram of forming capacitor holes in an exemplary embodiment of the present disclosure;

FIG. 9 is a schematic structure diagram of forming a support layer in an exemplary embodiment of the present disclosure;

FIG. 10 is a schematic structure diagram of a measured wafer in an exemplary embodiment of the present disclosure; and

FIG. 11 is an image of capacitor holes of a measured wafer in an exemplary embodiment of the present disclosure.

### DETAILED DESCRIPTION

Example embodiments are now described more comprehensively with reference to the accompanying drawings. However, the example embodiments can be implemented in various forms, and should not be construed as being limited to the examples set forth herein; on the contrary, the provision of these embodiments makes the present disclosure more comprehensive and complete, and fully conveys the concept of the example embodiments to those skilled in the art. The same reference numerals in the figures indicate the same or similar structures, and thus their detailed descriptions will be omitted. In addition, the drawings are only schematic illustrations of the present disclosure, and are not necessarily drawn to scale.

The described features, structures or characteristics can be combined in one or more embodiments in any suitable way. In the following description, many specific details are provided to provide a sufficient understanding of the embodiments of the present disclosure. However, those skilled in the art would realize that the technical solutions of the present disclosure can be practiced without one or more of the specific details, or other methods, components, materials, etc. can be used. In other cases, well-known structures, materials or operations are not shown or described in detail to avoid obscuring the main technical ideas of the present disclosure.

When a structure is “on” other structure, it may indicate that the structure is integrally formed on the other structure, or the structure is “directly” disposed on the other structure, or the structure is “indirectly” disposed on the other structure through another structure.

The terms “one”, “a”, and “the” are used to indicate the presence of one or more elements/components/etc. The terms “include” and “have” are used to indicate open inclusion and indicate that there may be additional elements/components/etc. in addition to the listed elements/components/etc. The terms “first” and “second” are only used as markers and are not a restriction on the number of objects.

In the related technology, in the manufacturing process of a semiconductor, in order to obtain a relatively large capacitance, a stacked layer is usually formed on a substrate, and capacitor holes that expose capacitor contact structures are formed in the stacked layer by using an etching equipment. The etching equipment may fail to etch through the stacked layer during etching, so that the bottoms of the corresponding capacitor holes fail to expose the capacitor contact structures, that is, defective capacitor holes are formed. The bottoms of the defective capacitor holes fail to expose the capacitor contact structures, so that the capacitor manufactured based on the defective capacitor holes cannot contact the capacitor contact structures, resulting in a decrease in device yield. In addition, the lower diameter of the defective capacitor hole is usually smaller than the upper diameter. Therefore, toppling easily occurs during subsequent manufacturing to short-circuit the capacitor.

At present, when etching defects of an etching equipment are detected, a high stacked layer structure formed with capacitor holes is usually directly scanned at a defect detection equipment to obtain an image of the capacitor holes. After that, whether the etching equipment has an etching defect is detected by analyzing the scanned image of the capacitor holes. However, in practical applications, the current stacked layer structure is relatively high, the capacitor holes formed are relatively deep, and the scanned images of the capacitor holes have little difference, so defective capacitor holes cannot be accurately identified, and then whether the etching equipment has an etching defect cannot be accurately determined.

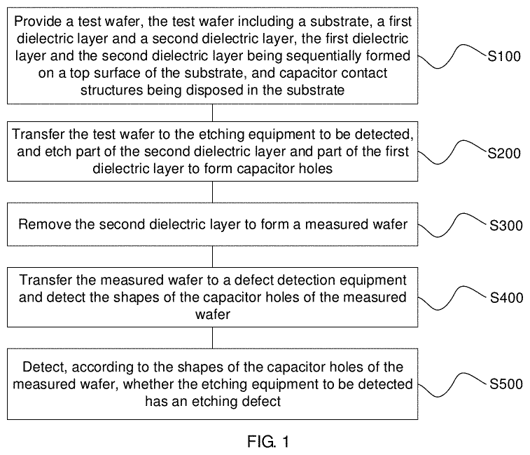

As shown in FIG. 1, an embodiment of the present disclosure provides a method for detecting etching defects of an etching equipment, including:

Step S100, providing a test wafer, the test wafer including a substrate, a first dielectric layer and a second dielectric layer, the first dielectric layer and the second dielectric layer being sequentially formed on a top surface of the substrate, and capacitor contact structures being disposed in the substrate;

Step S200, transferring the test wafer to the etching equipment to be detected, and etching part of the second dielectric layer and part of the first dielectric layer to form capacitor holes;

Step S300, removing the second dielectric layer to form a measured wafer;

Step S400, transferring the measured wafer to a defect detection equipment and detecting the shapes of the capacitor holes of the measured wafer; and

Step S500, detecting, according to the shapes of the capacitor holes of the measured wafer, whether the etching equipment to be detected has an etching defect.

In the method for detecting etching defects of an etching equipment provided in the present disclosure, the test wafer is transferred to the etching equipment to be detected, and part of the second dielectric layer and part of the first dielectric layer are etched to form capacitor holes. After the capacitor holes are formed, the second dielectric layer is removed to form a measured wafer. Then the measured wafer is transferred to the defect detection equipment to detect the shapes of the capacitor holes in the measured wafer, and whether the etching equipment to be detected has an etching defect is determined by comparing the image of the capacitor holes of the measured wafer with the image of normal capacitor holes. In this method, since the second dielectric layer is removed after the capacitor holes are formed, the depths of the capacitor holes are reduced. Therefore, when the defect detection equipment is used for detecting, the image of the capacitor holes of the measured wafer can be clearly detected, to determine whether there is a defective capacitor hole in the measured wafer, so as to determine whether the etching equipment to be detected has an etching defect. The method is simple and convenient, can accurately determine whether the etching equipment to be detected has an etching defect, greatly improves the efficiency of detecting the etching equipment, facilitates a technician to maintain the defective etching equipment in time, and further improves the yield of products.

The steps of the method for detecting etching defects of an etching equipment provided by the embodiment of the present disclosure will be described in detail below with reference to the accompanying drawings:

In step S100, a test wafer is provided, the test wafer including a substrate, a first dielectric layer and a second dielectric layer, the first dielectric layer and the second dielectric layer being sequentially formed on a top surface of the substrate, and capacitor contact structures being disposed in the substrate.

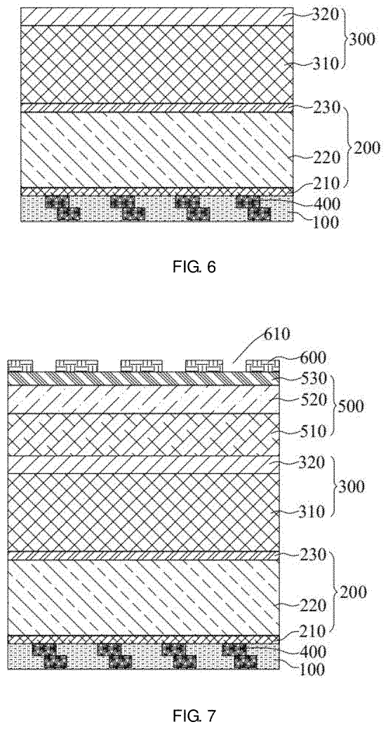

As shown in FIG. 6, the test wafer includes a substrate 100, a first dielectric layer 200 and a second dielectric layer 300. The substrate 100 may be a silicon substrate or other suitable substrate made of silicon, germanium, a silicon-germanium compound, etc. In some embodiments of the present disclosure, the substrate 100 is a silicon substrate. Of course, the substrate 100 is not limited thereto. In some other embodiments, the substrate 100 may also be other substrates known in the art.

Capacitor contact structures 400 are disposed in the substrate 100, and each capacitor contact structure 400 is electrically connected to a capacitor structure subsequently formed, so as to control the charge and discharge of the capacitor structures. The material of the capacitor contact structures 400 may be metallic tungsten. The number of capacitor contact structures 400 is plural, and two adjacent capacitor contact structures 400 are isolated from each other by the substrate 100 therebetween or the first dielectric layer 200. In the present disclosure, the process of forming the test wafer includes: providing a substrate 100 in which capacitor contact structures 400 are disposed; depositing a first dielectric layer 200 on a top surface of the substrate 100, the first dielectric layer 200 covering the surface of the substrate 100; and depositing a second dielectric layer 300 on the surface of the first dielectric layer 200 away from the substrate 100, the second dielectric layer 300 covering the surface of the first dielectric layer 200. The first dielectric layer 200 and the second dielectric layer 300 may be specifically formed by chemical vapor deposition, atomic layer deposition or physical vapor deposition. In the present disclosure, the method for forming the first dielectric layer 200 and the second dielectric layer 300 is not limited, and can be selected by technical personnel according to actual requirements.

In some embodiments of the present disclosure, the first dielectric layer 200 includes a first support layer 210, a first insulating layer 220 and a second support layer 230 sequentially formed. The first support layer 210 is formed on the top surface of the substrate 100, the first insulating layer 220 is formed on the surface of the first support layer 210 away from the substrate 100, and the second support layer 230 is formed on the surface of the first insulating layer 220 away from the substrate 100. The second dielectric layer 300 includes a second insulating layer 310 and a third support layer 320 sequentially formed. The second insulating layer 310 is formed on the surface of the second support layer 230 away from the substrate 100, and the third support layer 320 is formed on the surface of the second insulating layer 310 away from the substrate 100. The materials of the first support layer 210, the first insulating layer 220 and the second support layer 230 may be selected from silicon dioxide, silicon nitride boride, or silicon nitride. In a specific embodiment, the first support layer 210 is selected from silicon nitride or silicon nitride boride, the first insulating layer 220 is selected from silicon dioxide, and the second support layer 230 is selected from silicon nitride. The materials of the second insulating layer 310 and the third support layer 320 may also be selected from silicon dioxide, silicon nitride boride or silicon nitride. In a specific embodiment, the second insulating layer 310 is selected from silicon dioxide, and the third support layer 320 is selected from silicon nitride.

In other embodiments of the present disclosure, the substrate 100 may include a plurality of active regions and isolation structures (not shown) for defining the active regions, and each active region defines two source/drain regions. A plurality of word lines (not shown) and a plurality of bit lines (not shown) may be formed in the substrate 100, and each word line intersects the active region in the substrate 100 and separates the two source/drain regions to electrically connect with a gate of a transistor. Each bit line intersects the corresponding active region and electrically contacts one of the source/drain regions, and each capacitor contact structure 400 is disposed on the substrate 100 and corresponds to the other source/drain region.

In step S200, the test wafer is transferred to the etching equipment to be detected, and part of the second dielectric layer and part of the first dielectric layer are etched to form capacitor holes.

In this step, the test wafer is etched using the etching equipment to be detected to form capacitor holes. During semiconductor manufacturing, each equipment is regularly maintained. In the present disclosure, the etching equipment to be detected may be an etching equipment after maintenance, or an etching equipment that has not been maintained and is in any period of time.

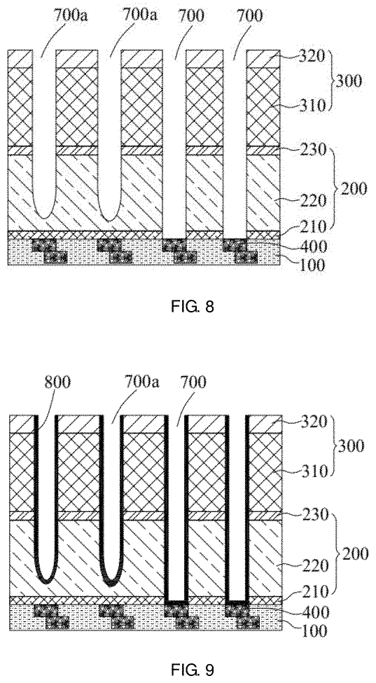

As shown in FIG. 8, in this step, part of the second dielectric layer 300 and part of the first dielectric layer 200 are etched using the etching equipment to be detected, to form capacitor holes in the first dielectric layer 200 and the second dielectric layer 300. The capacitor holes formed by etching may be normal capacitor holes 700 or defective capacitor holes 700a. The number of capacitor holes is plural. When the etching equipment to be detected has an etching defect, the etching equipment to be detected may fail to etch through the first dielectric layer 200 during etching, so that the bottoms of the corresponding capacitor holes fail to expose the capacitor contact structures 400, that is, defective capacitor holes 700a are formed. The bottoms of the defective capacitor holes 700a fail to expose the capacitor contact structures 400, so that the capacitors manufactured based on the defective capacitor holes 700a cannot contact the capacitor contact structures 400, resulting in a decrease in device yield.

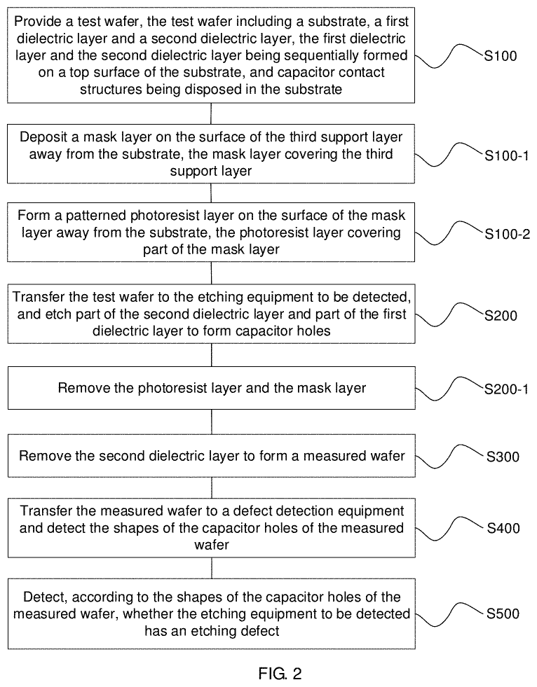

As shown in FIG. 2, in some embodiments of the present disclosure, before step S200, the method further includes:

Step S100-1, depositing a mask layer on the surface of the third support layer away from the substrate, the mask layer covering the third support layer; and

Step S100-2, forming a patterned photoresist layer on the surface of the mask layer away from the substrate, the photoresist layer covering part of the mask layer.

As shown in FIG. 7, in step S100-1, a mask layer 500 is deposited on the surface of the third support layer 320 away from the substrate 100, the mask layer 500 covering the third support layer 320. In some embodiments of the present disclosure, the material of the mask layer 500 may be selected from other suitable materials such as polysilicon, carbon, silicon and compounds thereof, and specifically may be one or more selected from silicon dioxide, silicon nitride, silicon oxynitride, carbon, etc., which is not limited here. In the present disclosure, the mask layer 500 may include a multilayer structure. As shown in FIG. 7, the mask layer 500 includes a polysilicon layer 510 formed on the surface of the third support layer 320, an oxide layer 520 formed on the surface of the polysilicon layer 510, and a carbon layer 530 formed on the surface of the oxide layer 520. Of course, in other embodiments, the mask layer 500 may also include other material layers, which are not specifically limited in the present disclosure.

As shown in FIG. 7, in step S100-2, a patterned photoresist layer 600 is formed on the surface of the mask layer 500 away from the substrate 100, the photoresist layer 600 covering the top surface of part of the mask layer 500. The photoresist layer 600 has a plurality of openings 610, and the orthographic projection of each of the openings 610 on the substrate 100 at least partially overlaps one of the capacitor contact structures 400. The openings 610 are used for etching to form the capacitor holes.

After the photoresist layer 600 is formed, step S200 is performed to etch the test wafer on which the mask layer 500 and the photoresist layer 600 are formed, to form the capacitor holes. Specifically, part of the mask layer 500, part of the second dielectric layer 300 and part of the first dielectric layer 200 are etched using the photoresist layer 600 as a mask and the substrate 100 as a stop layer, to form the capacitor holes.

As shown in FIG. 2, in some embodiments of the present disclosure, after step S200 and before step S300, the method further includes:

Step S200-1, removing the photoresist layer and the mask layer.

As shown in FIGS. 7 and 8, in this step, after the photoresist layer 600 and the remaining mask layer 500 are removed, a structure as shown in FIG. 8 is formed. In the structure, the capacitor holes include normal capacitor holes 700 that can expose the capacitor contact structures 400 and defective capacitor holes 700a that fail to expose the capacitor contact structures 400 due to etching defects.

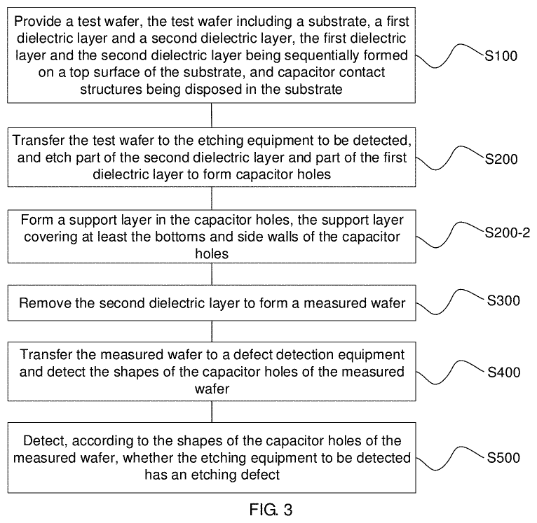

As shown in FIG. 3, in some embodiments of the present disclosure, after step S200 and before step S300, the method further includes:

Step S200-2, forming a support layer in the capacitor holes, the support layer covering at least the bottoms and side walls of the capacitor holes.

As shown in FIG. 9, in this step, a support layer 800 is formed in the capacitor holes, the support layer 800 covering at least the bottoms and side walls of the capacitor holes. The support layer 800 has a thickness of 8 to 12 nm. It should be noted here that the thickness of the support layer 800 should be less than ½ of the width of each capacitor hole, so as to prevent the too thick support layer 800 from filling the capacitor holes to affect subsequent detection on the shapes of the capacitor holes. In a specific embodiment, the material of the support layer 800 is selected from titanium nitride. In the semiconductor manufacturing process, the material of an electrode plate of a capacitor structure is generally selected from titanium nitride. In the present disclosure, the support layer 800 is made of titanium nitride. The titanium nitride is not only relatively hard to prevent the capacitor hole structure from toppling after the second dielectric layer is removed by polishing, but also can simulate a capacitor hole structure after an upper electrode plate is formed subsequently, to detect whether the etching equipment to be detected has etching defects more accurately.

In some embodiments, after step S200-1 is completed, that is, after the photoresist layer 600 and the mask layer 500 are removed, step S200-2 is performed. Of course, in other embodiments, step S200-2 may also be performed before step S200-1 to deposit the support layer 800, and then the photoresist layer 600, the mask layer 500, and the support layer 800 above the second dielectric layer 300 are removed to form the structure shown in FIG. 9.

In step S300, the second dielectric layer is removed to form a measured wafer.

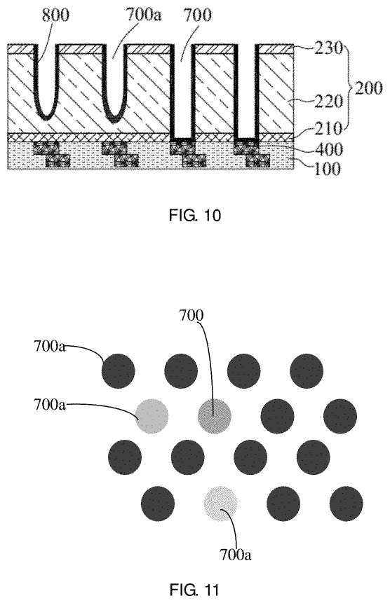

As shown in FIGS. 9 and 10, in this step, the second dielectric layer 300 is removed to form a measured wafer. In this step, after the second dielectric layer 300 is removed, a relatively low measured wafer and relatively shallow capacitor holes are obtained.

In some embodiments of the present disclosure, step S300 includes: removing the second dielectric layer and the support layer above the first dielectric layer by polishing to form the measured wafer.

As shown in FIG. 9, the formed support layer 800 covers the bottoms and side walls of the capacitor holes. In this step, the second dielectric layer 300 and the support layer 800 above the first dielectric layer 200 are removed by polishing to obtain the measured wafer as shown in FIG. 10. The measured wafer includes the substrate 100, the first dielectric layer 200, and the capacitor holes formed in the first dielectric layer 200.

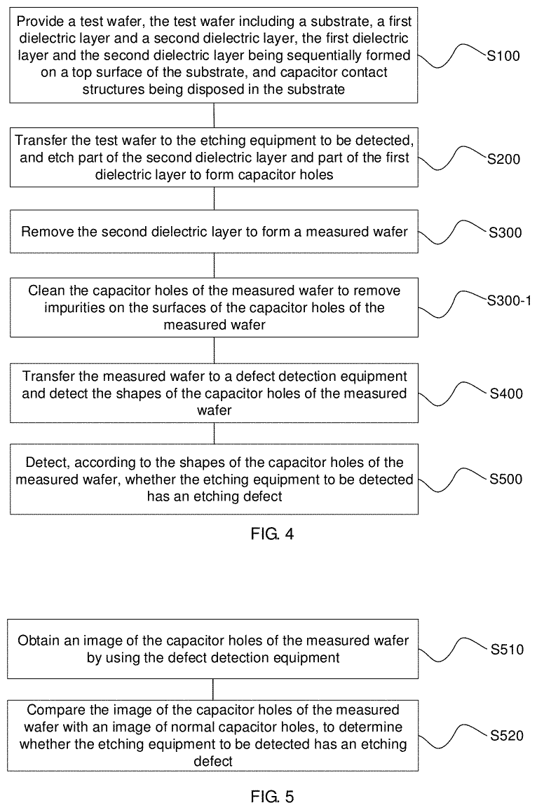

As shown in FIG. 4, in some embodiments of the present disclosure, after step S300 and before step S400, the method further includes:

Step S300-1, cleaning the capacitor holes of the measured wafer to remove impurities on the surfaces of the capacitor holes of the measured wafer.

In this step, the capacitor holes are cleaned to remove impurities in the capacitor holes. At this time, the support layer 800 formed in step S200-2 can protect the shapes of the capacitor holes from being affected during the cleaning, to ensure the accuracy of subsequent detection on the shapes of the capacitor holes. In some embodiments of the present disclosure, the capacitor hole of the measured wafer is cleaned with a diluted hydrofluoric acid solution, to remove impurities on the surfaces of the capacitor holes. The diluted hydrofluoric acid solution not only has a good cleaning effect, but also does not damage the support layer 800, which provides a guarantee for the subsequent detection of the capacitor holes and the formation of the capacitor structures. In this step, the dilution factor may be set according to the actual situation, which is not specifically limited in the present disclosure.

In step S400, the measured wafer is transferred to a defect detection equipment, to detect the shapes of the capacitor holes of the measured wafer.

In this step, the defect detection equipment is used to detect the capacitor holes of the measured wafer. The defect detection equipment may be a defect scanning equipment, and the scanning equipment scans the measured wafer for defects to obtain an image of the capacitor holes of the measured wafer.

In step S500, whether the etching equipment to be detected has an etching defect is determined according to the shapes of the capacitor holes of the measured wafer.

In this step, whether the etching equipment to be detected has an etching defect is determined according to the shape structures of the capacitor holes obtained by the defect detection equipment.

As shown in FIG. 5, in some embodiments of the present disclosure, step S500 includes:

Step S510, obtaining an image of the capacitor holes of the measured wafer by using the defect detection equipment; and

Step S520, comparing the image of the capacitor holes of the measured wafer with an image of normal capacitor holes, to determine whether the etching equipment to be detected has an etching defect.

When the etching equipment to be detected has an etching defect, the defective capacitor holes formed by etching are shallower than the normal capacitor holes, and the image of the capacitor holes of the measured wafer is different from the image of the normal capacitor holes accordingly. In some embodiments of the present disclosure, the image brightness obtained by detecting the defective capacitor holes 700a is different from the image brightness of the normal capacitor holes 700. Therefore, during actual detection, whether the etching equipment to be detected has an etching defect can be determined by comparing the image brightness of the capacitor holes of the measured wafer with the image brightness of the normal capacitor holes.

In some embodiments of the present disclosure, step S520 includes:

When the image brightness of part or all of the capacitor holes of the measured wafer is different from the image brightness of the normal capacitor holes, it is determined that the etching equipment to be detected has an etching defect. When the image brightness of all the capacitor holes of the measured wafer is the same as the image brightness of the normal capacitor holes, it is determined that the etching equipment to be detected does not have an etching defect.

As shown in FIG. 11, the image brightness of each capacitor hole of the measured wafer obtained by the defect detection equipment is different. It should be noted here that, due to different degrees of defects of different defective capacitor holes 700a, the corresponding image brightness is different, but in general, the image brightness of each defective capacitor hole 700a is different from the image brightness of the normal capacitor holes 700. In some embodiments of the present disclosure, the image brightness of the defective capacitor holes 700a are higher than the image brightness of the normal capacitor holes 700. In other embodiments of the present disclosure, the image brightness of the defective capacitor holes 700a are lower than the image brightness of the normal capacitor holes 700. The specific brightness is determined by the defect degree of each defective capacitor hole 700a itself, which is not limited in the present disclosure.

It should be noted that, although the various steps of the method in the present disclosure are described in a specific order in the drawings, this does not require or imply that these steps must be performed in the specific order, or that all the steps shown must be performed to achieve the desired result. Additionally or alternatively, some steps may be omitted, multiple steps may be combined into one step for execution, and/or one step may be decomposed into multiple steps for execution, etc., which should be regarded as a part of the present disclosure.

It should be understood that the present disclosure does not limit its application to the detailed structure and arrangement of components proposed in this specification. The present disclosure can have other embodiments, and can be implemented and executed in various ways. The aforementioned variations and modifications fall within the scope of the present disclosure. It should be understood that the present disclosure disclosed and defined in this specification extends to all alternative combinations of two or more individual features mentioned or obvious in the text and/or drawings. All these different combinations constitute multiple alternative aspects of the present disclosure. The embodiments of this specification illustrate the best way known for implementing the present disclosure, and will enable those skilled in the art to utilize the present disclosure.

1. A method for detecting etching defects of an etching equipment, comprising:
providing a test wafer, the test wafer comprising a substrate, a first dielectric layer and a second dielectric layer, the first dielectric layer and the second dielectric layer being sequentially formed on a top surface of the substrate, and capacitor contact structures being disposed in the substrate;
transferring the test wafer to the etching equipment to be detected, and etching part of the second dielectric layer and part of the first dielectric layer to form capacitor holes;
removing the second dielectric layer to form a measured wafer;
transferring the measured wafer to a defect detection equipment and detecting shapes of the capacitor holes of the measured wafer; and
detecting, according to the shapes of the capacitor holes of the measured wafer, whether the etching equipment to be detected has an etching defect.

2. The method for detecting etching defects of an etching equipment according to claim 1, wherein after the forming capacitor holes, and before the removing the second dielectric layer, the method further comprises:
forming a support layer in the capacitor holes, the support layer covering at least bottoms and side walls of the capacitor holes.

3. The method for detecting etching defects of an etching equipment according to claim 2, wherein the support layer has a thickness of 8 to 12 nm.

4. The method for detecting etching defects of an etching equipment according to claim 2, wherein a material of the support layer includes titanium nitride.

5. The method for detecting etching defects of an etching equipment according to claim 2, wherein the removing the second dielectric layer to form a measured wafer comprises:
removing the second dielectric layer and the support layer above the first dielectric layer by polishing to form the measured wafer.

6. The method for detecting etching defects of an etching equipment according to claim 1, wherein after the forming a measured wafer, and before the transferring the measured wafer to a defect detection equipment and detect shapes of the capacitor holes of the measured wafer, the method further comprises:
cleaning the capacitor holes of the measured wafer to remove impurities on surfaces of the capacitor holes of the measured wafer.

7. The method for detecting etching defects of an etching equipment according to claim 6, wherein the capacitor holes of the measured wafer are cleaned with a diluted hydrofluoric acid solution.

8. The method for detecting etching defects of an etching equipment according to claim 1, wherein the detecting, according to the shapes of the capacitor holes of the measured wafer, whether the etching equipment to be detected has an etching defect comprises:
obtaining an image of the capacitor holes of the measured wafer by using the defect detection equipment; and
comparing the image of the capacitor holes of the measured wafer with an image of normal capacitor holes, and determining whether the etching equipment to be detected has an etching defect.

9. The method for detecting etching defects of an etching equipment according to claim 8, wherein the comparing the image of the capacitor holes of the measured wafer with an image of normal capacitor holes, and determining whether the etching equipment to be detected has an etching defect comprises:
when an image brightness of all or part of the capacitor holes of the measured wafer is different from an image brightness of the normal capacitor holes, determining that the etching equipment to be detected has an etching defect; when the image brightness of all the capacitor holes of the measured wafer is the same as the image brightness of the normal capacitor holes, determining that the etching equipment to be detected does not have an etching defect.

10. The method for detecting etching defects of an etching equipment according to claim 1, wherein the first dielectric layer comprises a first support layer, a first insulating layer and a second support layer sequentially formed, and the second dielectric layer comprises a second insulating layer and a third support layer sequentially formed.

11. The method for detecting etching defects of an etching equipment according to claim 10, wherein before the transferring the test wafer to the etching equipment to be detected, and etching part of the second dielectric layer and part of the first dielectric layer to form capacitor holes, the method further comprises:
depositing a mask layer on a surface of the third support layer away from the substrate, the mask layer covering the third support layer; and
forming a patterned photoresist layer on a surface of the mask layer away from the substrate, the patterned photoresist layer covering part of the mask layer.

12. The method for detecting etching defects of an etching equipment according to claim 11, wherein the mask layer comprises a polysilicon layer, an oxide layer and a carbon layer sequentially formed.

13. The method for detecting etching defects of an etching equipment according to claim 11, wherein the patterned photoresist layer has a plurality of openings, and an orthographic projection of each of the openings on the substrate at least partially overlaps one of the capacitor contact structures.

14. The method for detecting etching defects of an etching equipment according to claim 11, wherein the transferring the test wafer to the etching equipment to be detected, and etching part of the second dielectric layer and part of the first dielectric layer to form capacitor holes comprises:
etching part of the mask layer, part of the second dielectric layer and part of the first dielectric layer by using the patterned photoresist layer as a mask and the substrate as a stop layer, to form the capacitor holes.

15. The method for detecting etching defects of an etching equipment according to claim 14, wherein after the transferring the test wafer to the etching equipment to be detected, and etching part of the second dielectric layer and part of the first dielectric layer to form capacitor holes, and before the removing the second dielectric layer to form a measured wafer, the method further comprises:
removing the patterned photoresist layer and the mask layer.
